(19) United States
(12) Patent Application Publication
(10) Pub. No.: US 2010/0015526 A1
(43) Pub. Date: Jan. 21, 2010

(54) Molecular Heterostructures for Energy Conversion and Storage

(75) Inventors: Arunava Majumdar, Orinda, CA (US); Rachel A. Segalman, Pleasanton, CA (US); Pramod Reddy, Ann Arbor, MI (US); Sung-Yeon Jang, Seoul (KR)

Correspondence Address: LAWRENCE BERKELEY NATIONAL LABORATORY, Technology Transfer & Intellectual Propery Managem, One Cyolotron Road MS 56A-120, BERKELEY, CA, 94720, US

(73) Assignee: THE REGENTS OF THE UNIVERSITY OF CALIFORNIA, Oakland, CA (US)

(21) Appl. No.: 12/538,804

(22) Filed: Aug. 10, 2009

Related U.S. Application Data
(63) Continuation of application No. PCT/US2008/054154, filed on Feb. 15, 2008.
(60) Provisional application No. 61/024,176, filed on Jan. 28, 2008.
(60) Provisional application No. 60/983,123, filed on Oct. 26, 2007.
(60) Provisional application No. 60/890,105, filed on Feb. 15, 2007.

(51) Int. Cl. H01M 4/60; H01L 29/66; H01G 9/00; H01L 35/30

(52) U.S. Cl. 429/215; 257/14; 361/500; 136/205; 257/E29.168

(57) ABSTRACT

The present invention provides for a metal-molecule heterostructure comprising (a) a plurality of metal, semimetallic or semiconducting nanoparticles, and (b) a plurality of electrically conductive organic molecules interspersed among the nanoparticles. The metal-molecular heterostructure is useful in a device, such as a thermoelectric energy converter, battery or capacitor.

### CROSS-REFERENCE TO RELATED APPLICATIONS

This application claims priority as continuation application to PCT International Patent Application Ser. No. PCT/US2008/054154, filed on Feb. 15, 2008, which claims priority to U.S. Provisional Patent Application Ser. Nos. 61/024,176, 60/983,123, and 60/890,105, filed on Jan. 28, 2008, Oct. 26, 2007, and, Feb. 15, 2007, respectively; which are hereby incorporated by reference.

### STATEMENT OF GOVERNMENTAL SUPPORT

The invention described and claimed herein was made in part utilizing funds supplied by the U.S. Department of Energy under Contract No. DE-AC02-05CH11231. The government has certain rights in this invention.

### FIELD OF THE INVENTION

This invention relates generally to metal-molecule heterostructures.

### BACKGROUND OF THE INVENTION

Study of charge transport in molecules is of fundamental interest with potential applications in molecular electronics and energy conversion devices. Current-voltage (I-V) characteristics of single molecules have been extensively investigated by trapping a single molecule in break junctions formed by mechanical strain, electromigration, and scanning tunneling microscopes. While such measurements have provided significant insight about charge transport through molecular junctions, critical aspects about the electronic structure cannot be uniquely obtained by I-V characteristics alone. For example, whether molecular junctions are p-type or n-type, i.e. the position of the Fermi level, E_{F}, of the metal contacts with respect to the highest occupied molecular orbitals (HOMO) and lowest unoccupied molecular orbitals (LUMO), generally remains unknown because of uncertainties in the microscopic details of the contacts.

It has been suggested that the sign of the Seebeck coefficient, S, of molecular junctions can indicate the sign of the charge carrier and the relative position of E_{F} with respect to the HOMO or LUMO levels. Indeed, thermopower measurements using a scanning probe microscope have yielded nanoscale spatial distributions of electron and hole concentrations in inorganic semiconductors and have led to chemical potential microscopy at the atomic scale. If thermopower measurements could be made for molecular junctions and for metal-molecule junctions, nanoscale agglomerates with desirable properties made from such junctions, could be found. Such agglomerates could be used to make small, low-cost thermoelectric converters with applications in electric power generation as well as in refrigeration.

The ability to measure the Seebeck effect in metal-molecule junctions also has deep implications on the use of molecules for other device applications. When molecules are sandwiched between metals or semiconductors, a key issue is the alignment of the electronic energy levels when a chemical bond is formed. This is critical for the operation and performance of molecular devices. However, so far, it has been very difficult to determine the energy level alignment present in such junctions. The measurement of the Seebeck coefficient would resolve this important issue and could be used directly to estimate the energy levels of such junctions. Such junctions can be used in molecular electronic devices for information processing and storage, as well as in molecular solar cells for converting sunlight to electricity. As a first step, what is needed is a reliable and efficient way to measure the Seebeck effect in metal-molecule agglomerates or heterostructures.

About 90 percent of the world's power (approximately 10 trillion Watts) is generated by heat engines that convert heat to mechanical motion, which can then be converted to electricity. However, nature requires payment of a penalty for this process; all of the heat cannot be converted to power, and about 15 trillion Watts of heat is released to the environment. The heat release temperature is often so close to ambient temperature that it is difficult to operate a gas or a steam turbine to use this low-grade heat to generate more power. Despite these losses, it is the technology of choice because heat engines are volumetric and, thereby, scalable to large power generation. If even a fraction of the low-grade lost heat could be converted to electricity in a cost-effective manner, the impact on energy production would be enormous, amounting to massive savings of fuel and atmospheric carbon dioxide.

Thermoelectric energy converters can convert low-grade heat to electricity directly using semiconducting materials. The devices rely on a phenomenon called the Seebeck effect, in which a voltage is produced when a temperature differential is applied across a material. Utilizing this effect, solid-state electric power generators as well as refrigerators have been built and are in use today. However, the widespread use of such devices is limited due to the efficiency and cost of the component materials. For example, today's thermoelectric generators operating across a temperature differential of 1000° C. at the hot side and 25° C. on the cold side (ΔT=975K) have efficiencies of about 7%; a traditional engine operating under similar conditions has an efficiency of about 20%. Furthermore, the materials of choice have been exotic, expensive alloys of bismuth and tellurium (e.g., Bi₂Te₃).

During the last 50 years, researchers have been working to improve the efficiency of thermoelectric materials. Progress has been extremely hard to come by, mainly due to coupling between various material properties, such as electrical conductivity, thermal conductivity, and Seebeck coefficient, which determine the efficiency of the device. Only recently through nanotechnology has significant progress been made in increasing the efficiency of thermoelectric materials. However, all currently-reported nanostructured thermoelectric material systems involve expensive inorganic materials and require high temperature semiconductor processing, making their widespread use prohibitive. What is needed is an inexpensive and efficient nanostructured thermoelectric material system.

### BRIEF DESCRIPTION OF THE INVENTION

The present invention provides for a metal-molecule heterostructure comprising (a) a plurality of metal, semimetallic or semiconducting nanoparticles, and (b) a plurality of electrically conductive organic molecules interspersed among the nanoparticles.

The present invention provides for any device comprising a metal-molecule heterostructure of the present invention.

In some embodiments, the device is an electronic device.

In some embodiments, the metal-molecule heterostructure is mechanically compliant and flexible, and/or a metal substrate is adjacent the metal-molecule heterostructure.

In some embodiments, the device further comprises an electrolyte material between the metal nanoparticles and the organic molecules.

In some embodiments, the device further comprises a first end of the metal-molecule heterostructure at a first temperature; a second end of the metal-molecule heterostructure at a second temperature less than the first temperature, the second end opposite the first end; an electrical connection between the first end and the second end.

In some embodiments, a first metal-molecule heterostructure acts as a first electrode and the device further comprises: a second metal-molecule heterostructure acting as a second electrode in electrical communication with the first electrode; an electrolyte material between the metal nanoparticles and the organic molecules and extending continuously from the first electrode to the second electrode.

In some embodiments, the first metal-molecule heterostructure acts as a first capacitor plate and further comprising: a second metal-molecule heterostructure acting as a second capacitor plate; an electrolyte material between the metal nanoparticles and the organic molecules and continuously extending continuously from the first plate to the second plate; an electrical connection between the first plate and the second plate, the electrical connection capable of maintaining an applied potential difference between the first plate and the second plate.

The present invention also provides for a thermoelectric energy converter, comprising: (a) a first metal-molecule heterostructure, comprising: (i) a plurality of metal, semimetallic or semiconducting nanoparticles, and (ii) a plurality of electrically conductive organic molecules interspersed among the nanoparticles; (b) a first end of the metal-molecule heterostructure at a first temperature; (c) a second end of the metal-molecule heterostructure at a second temperature less than the first temperature, the second end opposite the first end; and (d) an electrical connection between the first end and the second end.

The present invention also provides for a battery, comprising: (a) a first metal-molecule electrode, comprising: (i) a plurality of metal, semimetallic or semiconducting nanoparticles, and (ii) a plurality of electrically conductive organic molecules interspersed among the nanoparticles; (b) a second metal-molecule electrode in electrical communication with the first electrode; and (c) an electrolyte material between the metal nanoparticles and the organic molecules and extending continuously from the first electrode to the second electrode.

The present invention also provides for a capacitor, comprising: (a) a first metal-molecule capacitor plate, comprising: (i) a plurality of metal, semimetallic or semiconducting nanoparticles, and (ii) a plurality of electrically conductive organic molecules interspersed among the nanoparticles; (b) a second capacitor plate; (c) an electrolyte material between the metal nanoparticles and the organic molecules in both the first plate and the second plate and continuously extending continuously from the first plate to the second plate; and (d) an electrical connection between the first plate and the second plate, the electrical connection capable of maintaining an applied potential difference between the first plate and the second plate.

The present invention also provides for the use of any of the devices of the present invention.

The present invention also provides for the method of making of any of the devices of the present invention.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 is a schematic drawing that shows the scanning tunneling microscope (STM) that has been used to measure S_{junction}, according to an embodiment of the invention. Panel A shows a portion of the modified STM used. Panel B shows a more detailed diagram of the voltage amplifier circuit for the STM.

FIG. 2 is a schematic that shows the possible states of the molecular junction as the STM tip is withdrawn.

FIG. 3 (top) is a typical thermoelectric voltage curve for a Au substrate covered with BDT molecules and ΔT=20 K. FIG. 3 (bottom) shows how the thermoelectric voltage signal increases as ΔT is increased from 0 K to 30 K.

FIG. 4 shows histograms constructed from approximately 1000 measurements of ΔV at various values of ΔT for benzenedithiol (BDT). Panels A-C show the ΔV when ΔT equals 10K, 20K and 30K, respectively. Panel D shows the ΔVₚₑₐₖ against ΔT. Panel E shows a plot of S_{junction} as a function of molecule length.

FIG. 5 shows histograms constructed from approximately 1000 measurements of ΔV at various values of ΔT for dibenzenedithiol (DBDT). Panels A-C show the ΔV when ΔT equals 10K, 20K and 30K, respectively. Panel D shows the ΔVₚₑₐₖ against ΔT.

FIG. 6 shows histograms constructed from approximately 1000 measurements of ΔV at various values of ΔT for tribenzenedithiol (TBDT). Panels A-C show the ΔV when ΔT equals 10K, 20K and 30K, respectively. Panel D shows the ΔVₚₑₐₖ against ΔT.

FIG. 7 shows the results obtained for the Au-BDT-Au junction. Panel A shows the plot of the transmission function that was derived using the non-equilibrium Green's function formalism in conjunction with extended Huckel theory for the Au-BDT-Au junction. Panel B show the plot of S_{junction} as a function of energy for the Au-BDT-Au junction.

FIG. 8 shows schematic drawings of metal-molecule heterostructures or agglomerates.

FIG. 9 is a schematic drawing showing how thermoelectric metal-molecule heterostructures can be used to convert waste heat into electricity, according to an embodiment of the invention.

FIG. 10 shows how novel electrodes made of metal-molecule heterostructures can be used as electrodes in a battery.

FIG. 11 shows how novel electrodes made of metal-molecule heterostructures can be used as capacitor plates.

FIG. 12 is a schematic of an Au STM tip in proximity to the hot Au substrate.

FIG. 13 shows the histograms of the thermoelectric voltage obtained at a series of temperature biases for the respectively shown molecules (panel A), and the Voltage versus Temperature plots, wherein the slope is the thermopower (panel B). The benzene dithiol molecules used, wherein the addition of electron withdrawing groups decreases S while the addition of electron donating groups increases S relative to the original benzene dithiol molecule. The numbers on the graphs correspond as follows: 1: ΔT≈0K; 2: ΔT≈5K; 3: ΔT≈10K; 4: ΔT≈17K; 5: ΔT≈22K; 6: ΔT≈30K.

FIG. 14 shows that the thermopower data indicates that the addition of two methyl groups to the benzene dithiol (no. 1 curves) results in a shift of the HOMO level slightly closer to the Fermi level. This results in an overall increase in conductance (as shown at the top) as well as an overall increase in thermopower (bottom).

### DETAILED DESCRIPTION OF THE INVENTION

Before the present invention is described, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, the preferred methods and materials are now described. All publications mentioned herein are incorporated herein by reference to disclose and describe the methods and/or materials in connection with which the publications are cited.

It must be noted that as used herein and in the appended claims, the singular forms “a”, “and”, and “the” include plural referents unless the context clearly dictates otherwise. Thus, for example, reference to “a nanoparticle” includes a plurality of such nanoparticles, and so forth.

These and other objects, advantages, and features of the invention will become apparent to those persons skilled in the art upon reading the details of the invention as more fully described below.

### The Organic Molecule

The organic molecule is any suitable organic molecule which is conjugated. An organic molecule that is conjugated has alternating single and multiple bonds along one chain of the organic molecule. An organic molecule that is a conjugated has a semi-conducting or conducting electronic character.

In some embodiments, the organic molecule has the following chemical structure:

X—Yₙ—X(I);

wherein X is —SH or —CN; Y is independently in each instance

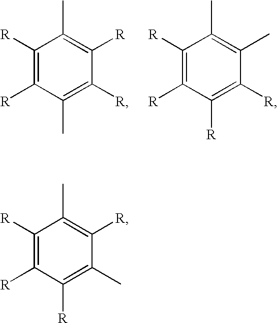

—CR═CR—, or —C≡C—; n is an integer from 1 to 10; and each R is independently H or a functional group which affects the electronic structure of the ring or double bond by donating electron as an electron donating group (EDG) or an electron withdrawing group (EWG). Suitable EDG include, but are not limited to, an amine, an alkyl, an hydroxyl, an ether, an alkenyl, and the like, wherein the EDG contains no more than 5 carbons. Suitable alkyls are methyl, ethyl, propyl, isopropyl, or butyl groups. Suitable EWG include, but are not limited to, a halogen, an aldehyde, a carbonyl, an ester, a carboxyl, a haloformyl, a haloalkyl, a nitrile, a sulfo, a nitro, and the like; wherein the EDG contains no more than 5 carbons. Suitable halogens are Cl, F, Br, and I.

In some embodiments, the organic molecule has chemical structure (I), wherein Y is independently in each instance

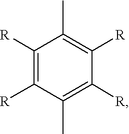

—CR═CR—, or —C≡C—; and R is described as above.

In some embodiments, the organic molecule has chemical structure (I), wherein Y is

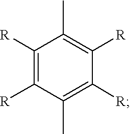

and R is described as above.

In some embodiments, the organic molecule has chemical structure (I), wherein n is an integer from 1 to 5.

In some embodiments, the organic molecule has chemical structure (I), wherein n is an integer from 1 to 3.

In some embodiments, the organic molecule has chemical structure (I), wherein Y is independently in each instance

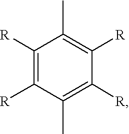

—CR═CR—, or —C≡C—; n is an integer from 1 to 5; and R is described as above.

In some embodiments, the organic molecule has chemical structure (I), wherein Y is independently in each instance

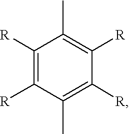

—CR═CR—, or —C≡C—; n is an integer from 1 to 3; and R is described as above.

In some embodiments, the organic molecule is an aromatic molecule. In some embodiments, the organic molecule has one or more aromatic rings. In the some embodiments, the organic molecule is a molecule having the following chemical structure:

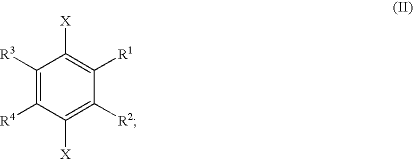

wherein X is —SH or —CN; and R¹, R², R³, and R⁴ are is independently H or a functional group which affects the electronic structure of the ring or double bond by donating electron as an EDG or an EWG (as defined above). In some embodiments, R¹ and R⁴ are the same substituent. In some embodiments, R¹ and R⁴ are the same substituent, while R² and R³ are the same substituent but different from the substituent of R¹ and R⁴. In some embodiments, R¹, R², R³, and R⁴ are the same substituent. In some embodiments, at least one, at least two, at least three, or all of R¹, R², R³, and R⁴ are an EDG or EWG (as defined above).

Suitable organic molecules with more than one ring structures include, but are not limited to, dibenzenedithiol (DBDT) and tribenzenedithiol (TBDT).

The chemical structure of DBDT is:

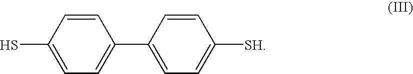

The chemical structure of TBDT is:

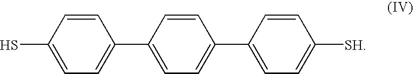

Suitable organic molecules with one ring structure include, but are not limited to, 1,4-benzenedithiol (BDT), tetraiodo-1,4-benzenedithiol (BDT4I), tetrabromo-1,4-benzenedithiol (BDT4Br), tetrachloro-1,4-benzenedithiol (BDT4Cl), tetrafluoro-1,4-benzenedithiol (BDT4F), and 2,5-diethyl-1,4-benzenedithiol (BDT2Et), 2,5-dimethyl-1,4-benzenedithiol (BDT2Me), and 1,4-benzenedicyanide (BDCN).

In the present invention, the organic molecule is bonded to the metal, semimetallic or semiconducting nanoparticles, electrodes, or plates, at or by X (the —SH or —CN groups).

The metal in the metal, semimetallic or semiconducting nanoparticles used in the present invention can comprise any metal capable of bonding with the organic molecule, such as gold, platinum, or the like. The electrodes used in the present invention can comprise any metal capable of bonding with the organic molecule, such as gold, platinum, or the like. The plates used in the present invention can comprise any metal capable of bonding with the organic molecule, such as gold, platinum, or the like.

One aspect of the invention is that the devices of the present invention are capable of, or use thereof results in or involves, an increase, or simultaneous increase, in the conductance and/or the thermopower of a metal-molecule-metal junction of a metal-molecule heterostructure of the device.

In general, S has been associated with bulk materials and is obtained by measuring the voltage created across a material in response to an applied temperature differential. In bulk materials, charge transport is diffusive in nature. But the concept of an effective S is also valid for junctions where the transport may be ballistic. Thus, in one embodiment of the invention, the Seebeck coefficient, S, has been measured for molecular junctions formed by trapping molecules between gold electrodes, imposing a temperature bias across the junction, and measuring the voltage generated across the electrodes. For such junctions a more general form of the Seebeck coefficient is used and is given as:

$$S = \frac{1}{eT} \frac{{\int }_{0}^{∞} σ ( E ) ( E - {E}_{F} ) d E}{{\int }_{0}^{∞} σ ( E ) d E} \qquad ( 1 )$$

where σ(E) is the energy-dependent differential electrical conductivity, E_{F} is the Fermi level (or more accurately, the chemical potential), e is the charge of an electron, and T is the absolute temperature; the denominator in Eq. 1 is the electrical conductivity, σ. As Eq. 1 suggests, S reflects the asymmetry of the distribution of conduction electrons or holes with respect to E_{F}. In bulk materials, this asymmetry results from energy-dependent carrier scattering or the asymmetry in the density of states. For ballistic transport, the asymmetry can be created by a potential barrier at a junction, such as that created between E_{F} of a metal and the HOMO or LUMO level of a molecule. Here, S is not an intrinsic property of a bulk material but of the heterojunction. Hence, it is called a junction Seebeck coefficient, S_{junction}. Because S_{junction} measures the size of an energy barrier, it does not depend on the number of molecules trapped between the electrodes and is, therefore, an intrinsic property of the junction. This is in contrast to the junction's electrical conductance, which depends on the number of molecules.

In one embodiment of the invention, an Au substrate was prepared by depositing 150 nm of gold in UHV onto a freshly cleaved surface of mica using a thermal evaporator. The gold surface was annealed in a hydrogen flame for approximately a minute and was coated with the desired molecules by immediately bringing the annealed Au surface in contact with a 1 mM solution of molecules in toluene. After exposing the substrates to the solution for ˜1 hr, the substrates were dried in a stream of N₂. All molecules used in the experiment had a purity of at least 99%. A gold STM tip was prepared by cutting 0.25 mm Au wires (99.999%) with a pair of scissors.

In some embodiments of the invention, the Au substrate was covered with benzenedithiol (BDT), dibenzenedithiol (DBDT) or tribenzenedithiol (TBDT) molecules prior to examination with a scanning tunneling microscope (STM). When the Au substrate is covered by thiol-terminated molecules, molecular bridges can form between the Au tip of the STM and the substrate, and the electrical conductance of single molecules can be monitored in air. When molecules of BDT, DBDT, or TBDT are trapped between the tip and substrate, and there is a superimposed ΔT, there is a thermoelectric voltage generated between the electrodes. The thermoelectric voltage lasts as long as one or more molecules are trapped and vanishes when all of the molecules have broken away.

A threshold conductance value 0.1 Gₒ, which is much larger than the electrical conductance of most organic single molecules, was chosen to indicate the formation of metal-molecule-metal junctions. Benzenedithiol, for example, has an electrical conductance of ˜0.01 Gₒ. Clearly, when a conductance of 0.1 Gₒ is reached, some molecules are trapped between the electrodes. Further, the threshold value was chosen to be smaller than Gₒ to prevent the Au STM tip from crashing into the Au substrate (the conductance of an Au—Au point contact is at least Gₒ).

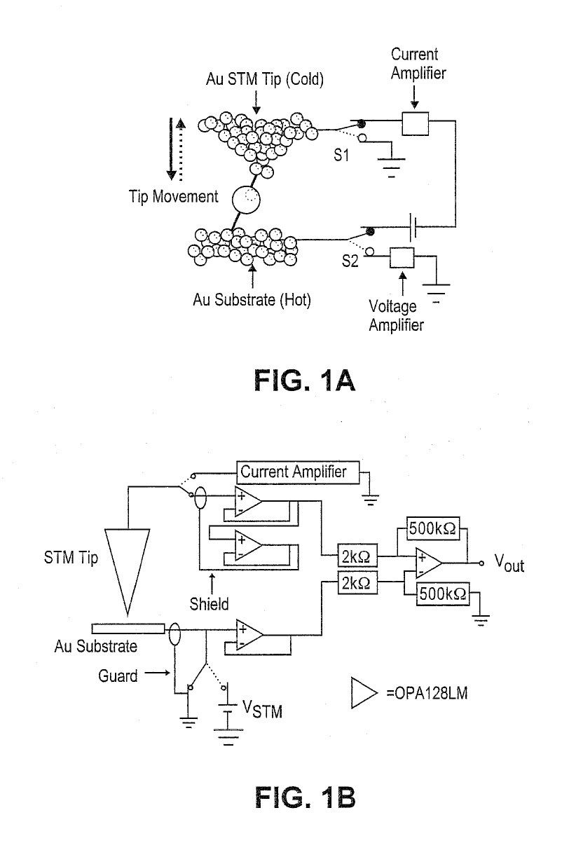

FIG. 1, panel A is a schematic drawing that shows a portion of a modified scanning tunneling microscope (STM) that has been used to measure S_{junction}, according to an embodiment of the invention. A more detailed diagram of the voltage amplifier circuit for the STM is shown in FIG. 1, panel B. A customized control circuit drives an Au STM tip at a constant speed toward a Au substrate in air under ambient conditions. The Au tip is kept in contact with a large thermal reservoir at room temperature, which maintains the tip temperature very close to ambient. The Au substrate can be heated with an electric heater to a desired temperature above ambient to create a tip-substrate temperature difference, ΔT. When the Au STM tip approaches the hot substrate, a tip-substrate voltage bias (and current amplifier S1) is applied and the current is continuously monitored. When the conductance reaches a sufficiently high threshold of 0.1 Gₒ, where Gₒ=2e²/h is the quantum of charge conductance, the proximity is sufficient to trap molecules between the electrodes. Once the threshold is reached, the voltage bias and the current amplifier (S1) are disconnected, and the voltage amplifier (S2) is connected to measure the tip-substrate thermoelectric voltage induced by the ΔT. The tip is then slowly withdrawn to a sufficiently long distance (˜15 nm) and the output voltage ΔV is monitored continuously with the tip grounded.

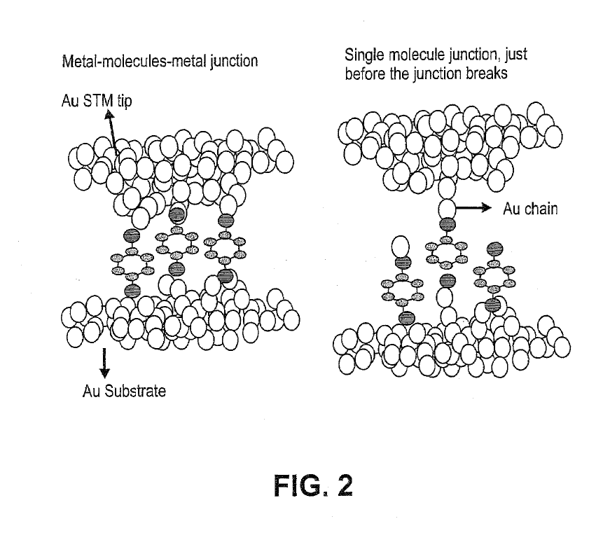

In one embodiment, the distance the STM tip is withdrawn before the disappearance of the thermoelectric voltage is ˜2 to 3 nm, which is much larger than the length of the molecules. FIG. 2 is a schematic that shows the possible states of the molecular junction as the STM tip is withdrawn. Without wishing to be bound to any particular theory, it may be that the large length is due to formation of gold chains from the tip and the substrate, as illustrated in FIG. 2. It may be that the thiol group on the molecule binds sufficiently strongly to Au, and that Au atoms are sufficiently mobile at room temperature, so that Au chains are formed both on the tip and on the substrate as the STM tip is pulled away. Multiple molecules may be trapped between the electrodes initially, and the molecules breakaway one at a time, as the STM tip is withdrawn from the substrate.

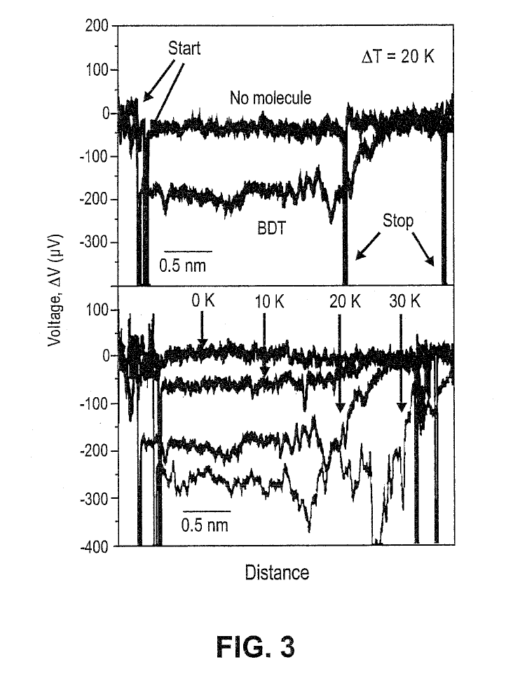

A typical thermoelectric voltage curve for a Au substrate covered with BDT molecules with ΔT=20 K is shown in FIG. 3 (top). A constant thermoelectric voltage of about ΔV=−200 μV (blue curve) is observed, which lasts until all of the molecules trapped in the junction break away. Note that the distance the tip travels (˜1 to 2 nm) before the molecule breaks away is much longer than the molecule length. It may be that the thiol group on the molecule binds sufficiently strongly to Au and that Au atoms are sufficiently mobile at room temperature, so that Au chains are formed both on the tip and the substrate when the STM tip is pulled away. In contrast to electrical conductance measurements where steps are seen in the electrical conductance as molecules break away one at a time, no steps are seen in the ΔV, which suggests that S_{junction}, is independent of the number of molecules. As the ΔT is increased from 0 K to 30 K, the thermoelectric voltage signal increases as shown in FIG. 3 (bottom). Control experiments performed on clean gold surfaces without any molecules, as shown in FIG. 2 (brown), demonstrate that no measurable ΔV is generated in the absence of molecules.

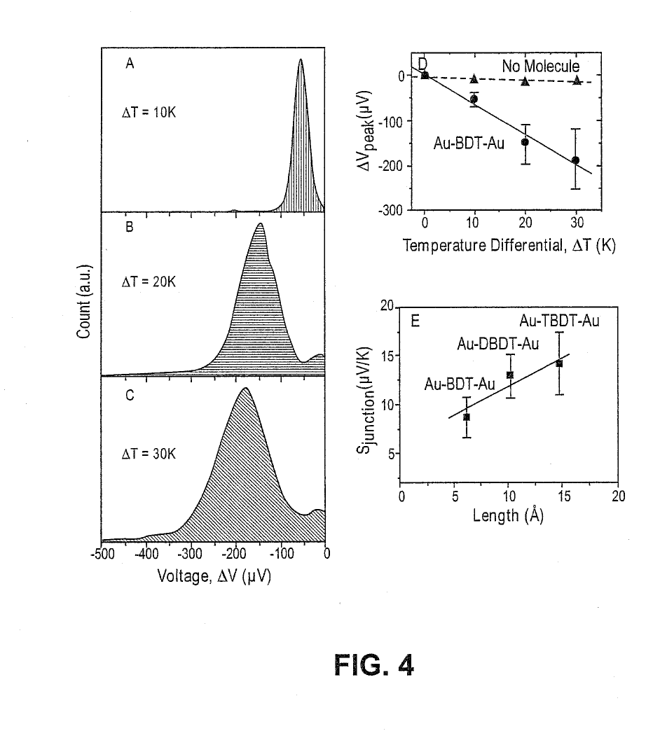

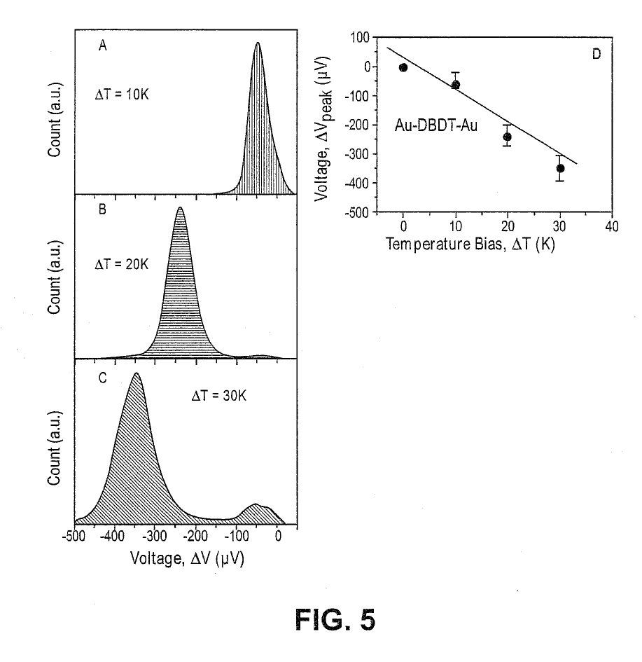

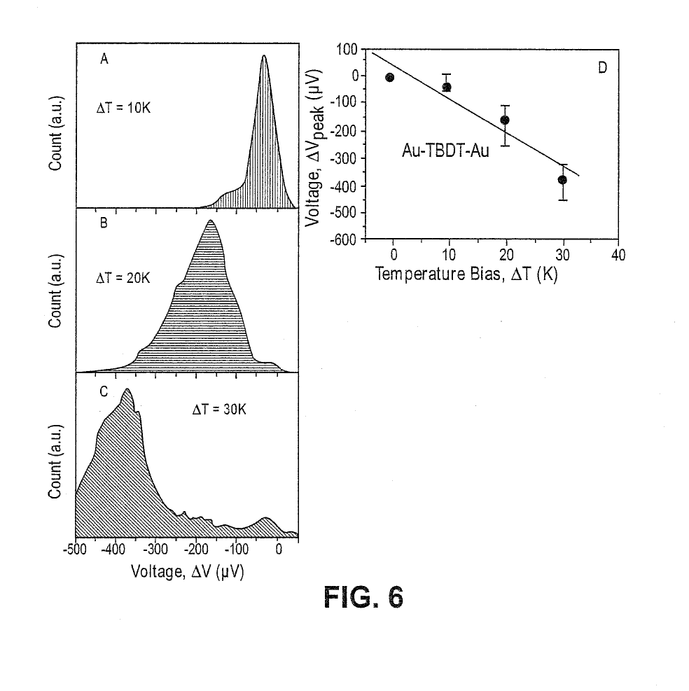

To obtain statistically significant ΔV values for a Au-BDT-Au junction, a Au-DBDT-Au junction, and a Au-TBDT-Au junction, roughly 1000 consecutive measurements were taken at each value of ΔT for each junction. These data were used to construct histograms for each temperature differential without any data pre-selection. The histograms thus obtained are shown in FIGS. 4, 5, and 6 for BDT, DBDT, and TBDT, respectively. In FIGS. 4-6, Panel A shows histograms for a tip-substrate temperature differential, ΔT, of 10 K; Panel B for ΔT=20 K; and Panel C for ΔT=30 K. The relation between S_{junction}, of the Au-molecule-Au junction and the measured voltage is given by:

$${S}_{junction} = {S}_{Au} - \frac{Δ V}{Δ T} \qquad ( 2 )$$

where S_{Au} is the Seebeck coefficient of bulk Au, which is ˜1.94 μV/K at 300K. In FIGS. 4D, 5D, 6D, ΔVₚₑₐₖ is plotted as a function of ΔT, where ΔVₚₑₐₖ corresponds to the ΔV at the peak of the distribution. The error bars correspond to the full-width half-maximum of the distributions. From the slope ΔV_{Peak}/ΔT and Eq. 1, one obtains the following values: S_{Au-BDTA-Au}=+8.7±2.1 μV/K; S_{Au-DBDT-Au}=+12.9±2.2 μV/K; and S_{Au-TBDT-Au}=+14.2±3.2 μV/K. FIG. 4E is a plot of S_{junction} as a function of molecule length. There seems to be a linear dependence of thermopower with molecule length, which is in contrast to the exponential dependence of electrical resistance generally attributed to tunneling across the molecule.

The relative position of the HOMO and LUMO levels of the metal electrodes with respect to E_{F} can be related to the measured value of S_{junction}. The Landauer formula is used to relate S_{junction} to the transmission function, τ(E). It has been shown that S_{junction} can be obtained as:

$${S}_{junction} = - \frac{{π}^{2} {k}_{B}^{2} T}{3 e} \frac{\partial ln ( τ ( E ) )}{\partial E} {\vert}_{E = {E}_{F}} \qquad ( 3 )$$

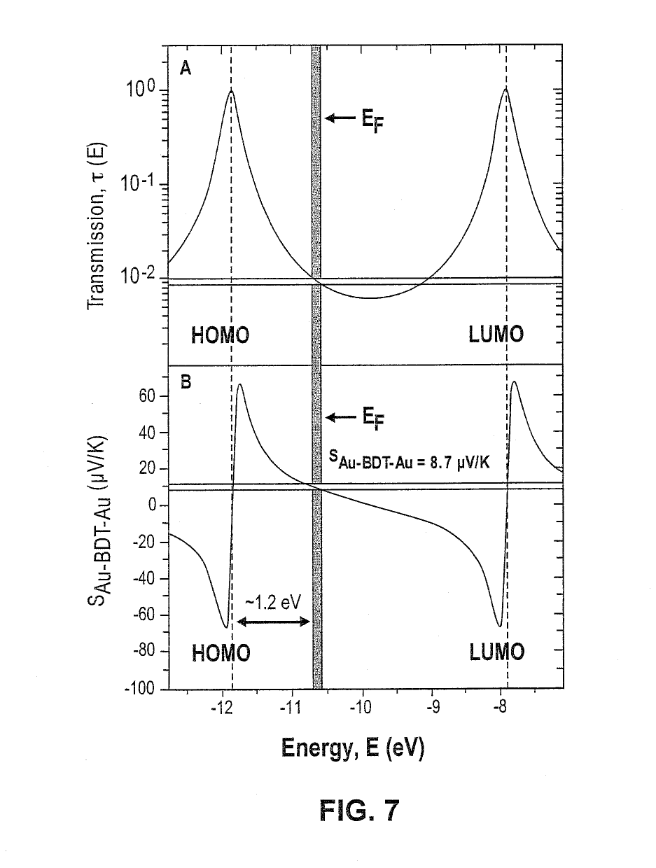

The transmission function for the case of the Au-BDT-Au junction, that was derived using the non-equilibrium Green's function formalism in conjunction with extended Huckel theory, is shown in FIG. 7A. It is clear that τ(E)˜1 when the E_{F} aligns with either the HOMO or the LUMO levels and decreases rapidly to below 0.01 between the HOMO and the LUMO levels. Using the transmission function in Eq. 3, S_{junction} can be calculated (FIG. 7B). S_{junction} is positive (p-type) if E_{F} is closer to the HOMO level and negative (n-type) if E_{F} is closer to the LUMO level. For S_{Au-BDTA-Au}=+8.7±2.1 μV/K, FIG. 7B shows that E_{F} is ˜1.2 eV from the HOMO level. The value of the transmission function at this relative position of the Fermi level can be seen to be τ(E)˜0.01 from FIG. 7A. In the Landauer formalism, the conductance G_{molecule} can be related to the transmission function at E_{F} as:

$${G}_{molecule} \approx \frac{2 {e}^{2}}{h} τ ( E ) {\vert}_{E = {E}_{F}} = τ ( E ) {\vert}_{E = {E}_{F}} {G}_{o} \qquad ( 4 )$$

Eq. 4 implies that the electrical conductance of BDT should be ˜0.01 Gₒ. The estimated value of the conductance is in excellent agreement with the measured electrical conductance of BDT.

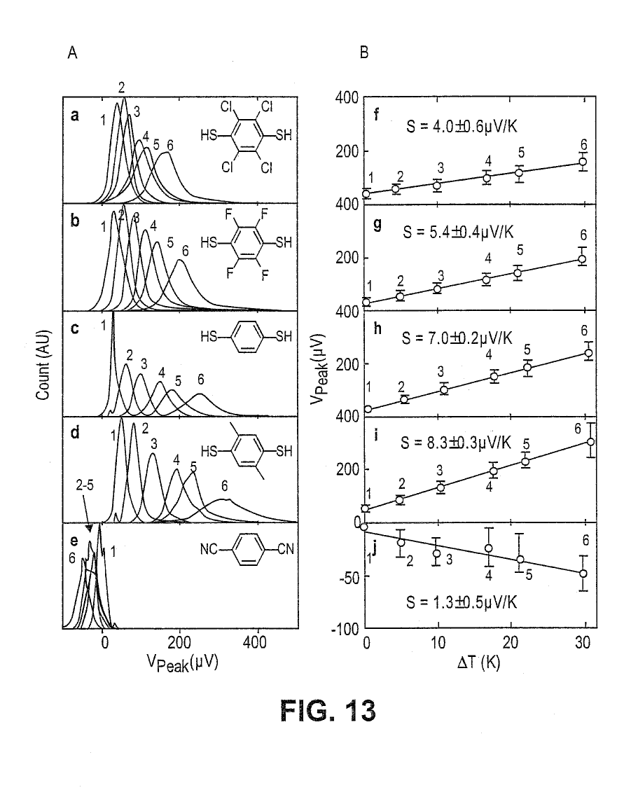

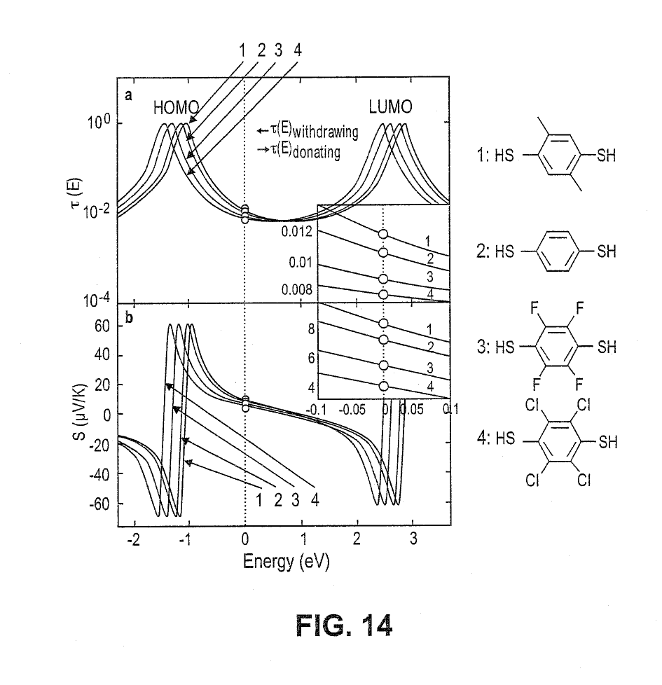

In one aspect of the invention, the probability of charge transport through a metal-molecule-metal junction is described by the transmission function (TτE)). The thermopower (S_{Junction}) and conductance (G_{Junction}) of the junction³ are related to the transmission function τ(E) as follows,

$$\begin{matrix}{S}_{junction} = - \frac{{π}^{2} {k}_{B}^{2} T}{3 e} \frac{\partial ln ( τ ( E ) )}{\partial E} {\vert}_{E = {E}_{F}} , and & ( 3 ) \\ {G}_{junction} \approx \frac{2 {e}^{2}}{h} τ ( E ) {\vert}_{E = {E}_{F}} = τ ( E ) {\vert}_{E = {E}_{F}} {G}_{o} ; & ( 4 )\end{matrix}$$

where e is the charge of a proton, k_{B} is the Boltzmann constant, and T is the average absolute temperature of the junction. Essentially, G_{Junction} characterizes the value of the transmission function at the Fermi level while S_{junction} is related to its slope at the Fermi level. Both G_{Junction} and S_{junction} are maximized when the Fermi Level is located near the peaks in τ(E). The Fermi-level is set by the metal electrode, but the position of the peaks in τ(E) can be tuned by tuning the chemical structure of the molecule. The addition of one or more electron donating substituents (such as, an alkyl group, such as a methyl group) stabilizes the highest occupied molecular orbital (HOMO and shifts it slightly closer to the Fermi level (shifting the orange line of FIG. 7 to the left). This results in an unprecedented simultaneous increase in both S_{junction} and G_{junction} as shown in FIG. 13. This simultaneous increase in conductance and thermopower is not possible in traditional materials, but this level of control is absolutely necessary for tuning of thermoelectric efficiency (ZT), but has hitherto been impossible to attain in simple inorganic materials. Conversely, the addition of one or more electron withdrawing groups (such as, a halogen, such as chlorine) shifts the LUMO slightly closer to the Fermi level resulting. When the LUMO is sufficiently shifted, the junction begins to transport electrons instead of holes. In the case shown in FIG. 13, however, the LUMO is shifted only modestly resulting in a decrease in both S_{junction} and G_{junction}, but this suggests feasible routes towards simultaneous tuning of thermopower, conduction, and charge carrier type through molecular design.

While the substituents move the relative position of HOMO and LUMO with respect to E_{F} in the range 0.1-0.3 eV such that S_{junction} ranges from 4-8 μV/K, changing the end groups which bind to the electrodes induces a larger change in S_{junction}. As shown in FIG. 13, when the end groups on benzene are changed from thiol to cyanide, a change in the sign of the thermopower from positive to negative is observed, which implies that electron transport in Au-BDCN-Au junction is primarily through the LUMO. Thus the contact between the metal and the molecule can be tuned to induce large changes in the electronic transport properties of such junctions. For a given metal-molecule-metal junction, the junction can be engineered by changing one or both the end groups on the molecule which bind to the metal. Such a junction can then be fine tuned by the addition of substituents to the molecule, which induces small and predictable changes to the junction. Thus by varying endgroups and substituents one can engineer metal-molecule heterostructures with targeted properties. Furthermore, this shifting of the peaks of the transmission function (τ(E)) with respect to E_{F} indicates that both the conductance and thermopower may be increased simultaneously in organic molecules.

Junction Seebeck coefficient measurements can provide insight into the electronic structure of the heterojunction, but the results also bear on thermoelectric energy conversion based on molecules. The best efficiency in thermoelectric energy conversion can be achieved if charge transport occurs through a single energy level. Single-level transport is, however, difficult to realize in inorganic materials. Metal-molecule-metal heterojunctions are ideal in this regard since they: (i) provide transport either through the HOMO or LUMO levels; and (ii) have very low vibrational heat conductance because of large mismatch of vibrational spectra between the bulk metal and discrete molecules. Hence, such a hybrid material offers the promise of efficient thermoelectric energy conversion devices. The length dependence of molecular junction Seebeck coefficients has been discussed above in regard to FIG. 4E for BDT, DBDT, and TBDT molecules. But there are other ways of tuning thermopower, such as by introducing various chemical moieties into the molecule or by controlling the metal-molecule chemical bond.

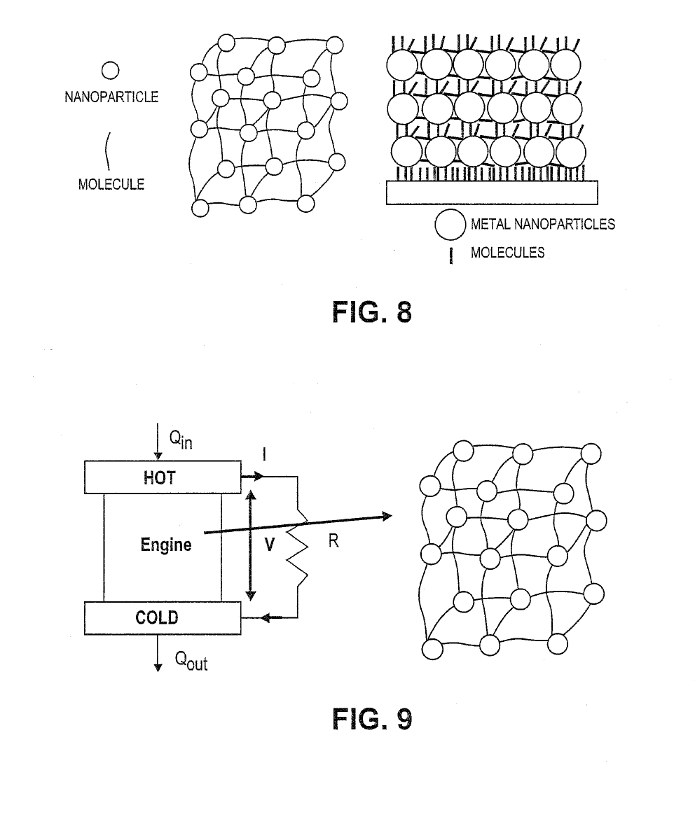

Molecular heterostructures made by sandwiching molecules between metal, semimetal, or semiconductor nanoparticles (FIG. 8) can have very interesting properties that make them attractive for energy conversion and energy storage applications. It will be understood that the term “metal nanoparticle,” as used herein, includes semimetal or semiconductor nanoparticles also. Thermoelectric effects in metal-molecule junctions can be measured as discussed above. From the measurements, the relative positions of the energy levels contributing to charge transport with respect to the Fermi level of the metal can be determined. By varying the structure of the molecules tune the relative position of the energy levels contributing to charge transport with respect to the Fermi level can be tuned, thus tuning electrical conductance and thermopower of the metal-molecule junctions. By engineering the molecular structure suitably, high electrical conductance and thermopower in metal-molecule junctions can be achieved.

The efficiency of the device increases when the electronic structure of the molecules is tuned to increase the thermopower and electrical conductance of metal-molecule junctions. Further, the efficiency increases also because the thermal conductivity of the metal-molecule heterostructures is very low due to a huge mismatch between the metal and molecule in the phonon density of states. Cost effectiveness is achieved by using inexpensive metal, semimetallic or semiconducting nanoparticles and organic molecules in the heterostructures.

The thermoelectric nanostructured materials systems disclosed herein mark a major departure from traditional thermoelectric inorganic semiconductor materials. A whole new field of molecular thermoelectrics has been opened up, and it is now possible to tune the relevant properties of the metal-molecule junctions using the chemistry of the molecules and their contact with metal. Inexpensive organic molecules and metal nanoparticles offer the promise of low-temperature solution processing and small, low-cost plastic-like power generators and refrigerators. By self-assembling metal-molecule heterostructures or agglomerates using inexpensive nanoparticles and organic molecules, examples of which are shown in FIG. 8, new thermoelectric materials that are cost effective and efficient can be created. FIG. 9 is a schematic drawing showing how metal-molecule heterostructures can be used to convert waste heat into electricity, according to an embodiment of the invention.

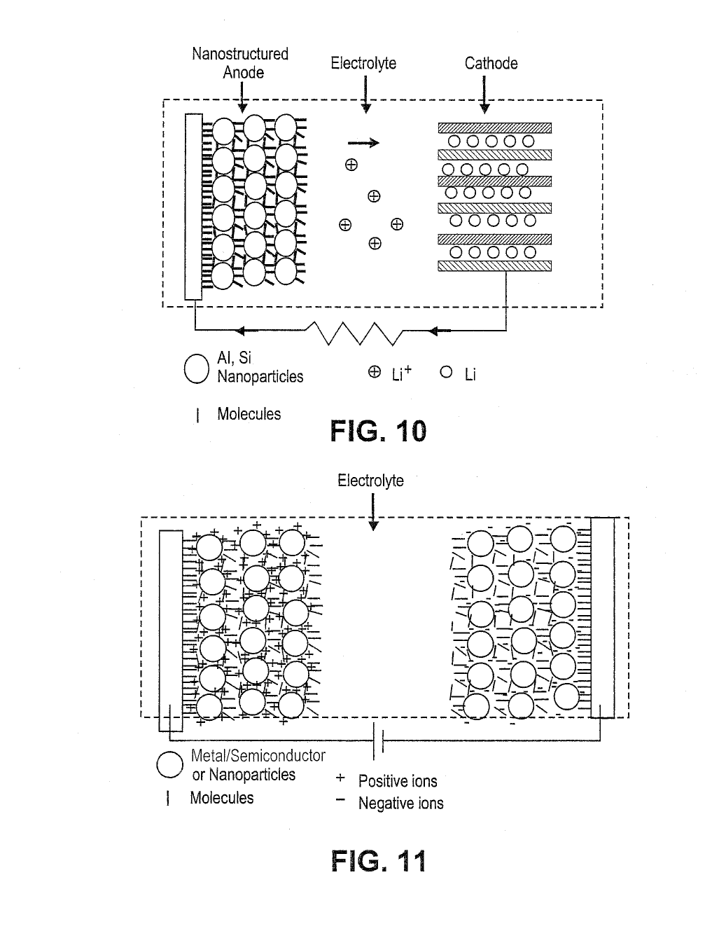

In another embodiment of the invention, FIG. 10 shows how novel electrodes made of metal-molecule heterostructures can be used in a battery. Metal-molecule agglomerates made up of molecules with large electrical conductance and metal nanoparticles are used to increase the energy density of batteries. In one exemplary embodiment, agglomerates of conducting organic molecules such as benzenedithiol, dibenzenedithiol, or tribenzenedithiol and nanoparticles of Si, Al, or other materials that alloy with lithium are used as an anode in a lithium ion battery. The conducting molecules provide a route for easy transport of electrons as the Li⁺ ions are transported in the electrolyte. The electrodes allow storage of much more lithium per unit mass of the anode than can traditional anodes currently used in lithium ion batteries. Moreover, metal-molecule agglomerate electrodes made of materials appropriate for the system can be used in other battery systems as well.

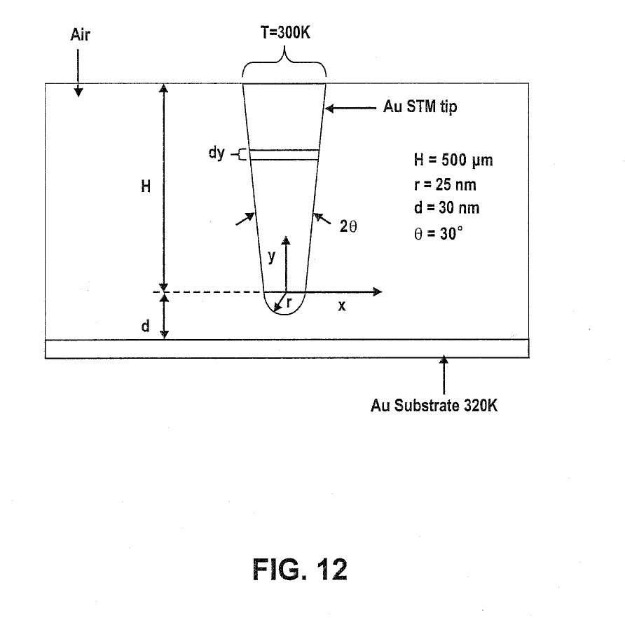

In another embodiment of the invention, a double layer capacitor uses plates (electrodes) made of metal-molecule agglomerates. The surface area of metal-molecule agglomerates is extremely high, thus the surface area of the electrodes made using metal-molecule agglomerates is also extremely high per unit volume or weight. The amount of charge that can be stored in a capacitor, of course, is directly proportional to the surface area of the electrodes. Capacitors such as the example shown in FIG. 11 can store much more charge per unit area of electrode than is possible at present with conventional electrodes made of activated carbon used in double layer capacitors. Capacitor electrodes made of activated carbon have an effective surface area of approximately 500 to 2000 m²/gm of active material. Metal molecule-agglomerate capacitor electrodes have an effective surface area of more than 4000 m²/gm.

Derivation of the relationship between measured voltage and junction Seebeck coefficient (S_{junction}):

Thermopower is defined by the following relation:

\vec{E}=S∇T; [symbol] −∇V=S∇T (5)

where \vec{E} is the electric field, on integrating Eq. 5:

V₂−V₁=−(S_{junction})(T₂−T₁) (6)

where V₂ is the voltage at the junction of the molecule and the substrate and V₁ is ground. T₂ is the temperature of the substrate and T₁ is the ambient temperature. Further,

V₃−V₂=−(S_{Au})(T₃−T₂) (7)

where V₃ is the voltage and T₃ is the temperature at point 3 (the end of gold wire). Upon adding Eq. 6 and Eq. 7:

V₃−V₁=(S_{Au}−S_{junction})(T₂−T₁) (8)

From which it is clear that the junction Seebeck coefficient S_{junction} is given by:

$${S}_{junction} = {S}_{Au} - ( \frac{{V}_{3} - {V}_{1}}{Δ T} ) \qquad ( 9 )$$

### Determination of STM Tip Temperature

The temperature at the end of the STM tip making contact with the molecules is a crucial parameter in these experiments. This temperature is held at ambient by contact to a large thermal mass. An estimation of the exact temperature is shown below. The mechanisms involved in the transport of heat are: (1) conduction through air, and/or (2) conduction through the liquid meniscus or organic molecules which may be bridging the gap between the substrate and the tip. Our earlier work on thermal transport mechanisms across nanoscale junctions demonstrated that heat transport through air (conduction) is much larger than the heat transport through the material (liquid or molecular) in the gap. In fact, that heat transport through the liquid meniscus is negligible.

A schematic of an Au STM tip in proximity to the hot Au substrate is shown in FIG. 12. The temperature distribution in the Au STM tip end as a function of substrate distance for this geometry can be computed by using a model. The one dimensional heat conduction equation in the tip is written as:

$$\frac{d }{d y} [ {A}_{t} ( y ) {k}_{t} ( y ) \frac{d T ( y )}{d y} ] - p ( y ) {h}_{a} ( y ) tan ( θ ) ( T ( y ) - {T}_{sub} ) = 0 \qquad ( 10 )$$

Here kₜ and Aₜ are the thermal conductivity and the cross-sectional area of the tip respectively, T is the temperature of the tip, T_{sub} is the substrate temperature, θ is the half angle of the conical tip, and p is the perimeter of the cross section of the tip. For each point on the perimeter of the tip, it is assumed that heat is conducted by air between the point and a point immediately below on the substrate. These two points are treated as if they are located on two parallel plates.

This simplified picture of heat transport in air is captured in the second term of Eq. 10. The distance between the two corresponding points on the tip and substrate is (y+d). The air conduction coefficient ha has to be written in different forms for different values of (y+d)/l, where l is the mean free path of molecules in air (˜60 nm under ambient conditions). For (y+d)/l>100, a constant temperature gradient is assumed at the air gap and hₐ=αkₐ/(y+d), where ka is the thermal conductivity of bulk air and α is a geometry factor to accommodate the fact that the tip and the substrate are not exactly two parallel plates and is approximately 0.8±0.1 for our geometry. For 1<(y+d)/l<100, a temperature discontinuity may develop as intermolecular collisions become less frequent and molecules arriving at the solid surfaces are unable to come into equilibrium with the surface. In this so-called slip regime,

$${h}_{a} = \frac{α {k}_{a} / ( y + d )}{1 + 2 fl / ( y + d )} ; f = \frac{2 ( 2 - A ) γ}{A ( γ + 1 ) Pr} , \qquad ( 11 )$$

where A is a thermal accommodation coefficient (˜0.9 for air), γ is the ratio of air heat capacities, and Pr is the Prandtl number. In a regime where (y+d)/l<1, air molecules are transported ballistically from one surface to another, and ha is written as,

$${h}_{a} = \frac{α {k}_{a}^{′}}{( y + d ) ( 1 + 2 f )} ; {k}_{a}^{′} = CV ( y + d ) / 3 , \qquad ( 12 )$$

where k′ₐ is the thermal conductivity of air in the free molecule flow regime, and C and V are the heat capacity and root-mean-square velocity of air molecules, respectively.

The results of the above set of equations represent was previously shown to be in good agreement with experiments. In this case, the above equations can be solved in conjunction with the boundary conditions that specify the substrate temperature and the Au STM temperature far away from the tip-substrate interface. When solved numerically, one can show using this model that even when the tip-substrate gap (d-r) is reduced to 1 nm, the temperature at the very end of the tip is less than T_{ambient}+0.01(T_{sub}−T_{ambient}), i.e the increase in tip temperature is less than one percent of the temperature differential applied across the substrate and tip. This applies even when the tip-sample distance (d-r) is reduced to less than a nanometer. This very small increase in temperature is essentially due to the large thermal conductivity of Au (˜317 W/m-K), which keeps the apex of the tip at the same temperature as the large thermal mass it is connected to. This is also in agreement with the results published earlier where it was shown that for a Si AFM tip with a thermal conductivity of 148 W/m-K, the temperature at the tip of the AFM is within one percent of the temperature differential applied. The boundary condition used in this model corresponded to the temperature at H=500 μm from the Au STM tip, i.e., on the shank of the tip. It was verified that the temperature at this location was indeed equal to the ambient temperature by measuring the temperature at H=500 μm using a fine (12.7 μm, dia) K type thermocouple.

### Method 1:

In one embodiment, metal-molecule heterostructures are made using the following steps:
(1) A gold coated substrate is dipped into a 1 millimolar solution of molecules terminated by thiol (—SH) groups on either ends, resulting in the deposition of a monolayer of molecules on the surface;
(2) The substrate is immersed in a solution with suspended gold nanoparticles, resulting in the formation of a layer of gold nanoparticles on the monolayer of molecules;
(3) The substrate from Step 2 is submerged again in a solution containing dithiol molecules, to form one more layer of molecules; and
(4) Step 2 and Step 3 can be repeated multiple times to build up a metal-molecule heterostructure to whatever size is desired.

### Method 2:

In another embodiment, metal-molecule heterostructures are made as follows:

A solvent with suspended nanoparticles is mixed with a solution containing thiol terminated molecules to spontaneously form metal-molecule agglomerates.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

While the present invention has been described with reference to the specific embodiments thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective, spirit and scope of the present invention. All such modifications are intended to be within the scope of the claims appended hereto,

We claim:

1. An electronic device, comprising:
a first metal-molecule heterostructure, comprising;
a plurality of metal, semimetallic or semiconducting nanoparticles; and
a plurality of electrically conductive organic molecules interspersed among the nanoparticles.

2. The device of claim 1, wherein the heterostructure is mechanically compliant and flexible.

3. The device of claim 1, further comprising a metal substrate adjacent the first heterostructure.

4. The device of claim 1, further comprising an electrolyte material between the metal nanoparticles and the organic molecules.

5. The device of claim 1, further comprising:
a first end of the metal-molecule heterostructure at a first temperature;
a second end of the metal-molecule heterostructure at a second temperature less than the first temperature, the second end opposite the first end;
an electrical connection between the first end and the second end.

6. The device of claim 1 wherein the first metal-molecule heterostructure acts as a first electrode and further comprising:
a second metal-molecule heterostructure acting as a second electrode in electrical communication with the first electrode;
an electrolyte material between the metal nanoparticles and the organic molecules and extending continuously from the first electrode to the second electrode.

7. The device of claim 1 wherein the first metal-molecule heterostructure acts as a first capacitor plate and further comprising:
a second metal-molecule heterostructure acting as a second capacitor plate;
an electrolyte material between the metal nanoparticles and the organic molecules and continuously extending continuously from the first plate to the second plate;
an electrical connection between the first plate and the second plate, the electrical connection capable of maintaining an applied potential difference between the first plate and the second plate.

8. The device of claim 1, wherein the organic molecules have the following chemical structure:
X—Yₙ—X(I);
wherein X is —SH or —CN; Y is independently in each instance 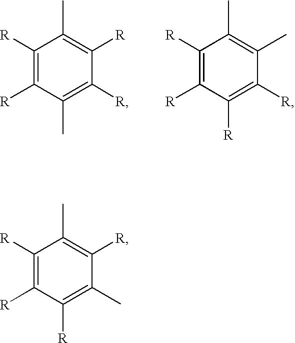
—CR═CR—, or —C≡C—; n is an integer from 1 to 10; and each R is independently H or an amine, alkyl, hydroxyl, ether, alkenyl, halogen, aldehyde, carbonyl, ester, carboxyl, haloformyl, haloalkyl, nitrile, sulfo, or nitro, wherein R contains no more than 5 carbons.

9. A thermoelectric energy converter, comprising:
a first metal-molecule heterostructure, comprising;
a plurality of metal, semimetallic or semiconducting nanoparticles; and
a plurality of electrically conductive organic molecules interspersed among the nanoparticles;
a first end of the metal-molecule heterostructure at a first temperature;
a second end of the metal-molecule heterostructure at a second temperature less than the first temperature, the second end opposite the first end; and
an electrical connection between the first end and the second end.

10. A battery, comprising:
a first metal-molecule electrode, comprising;
a plurality of metal, semimetallic or semiconducting nanoparticles; and
a plurality of electrically conductive organic molecules interspersed among the nanoparticles;
a second metal-molecule electrode in electrical communication with the first electrode; and
an electrolyte material between the metal nanoparticles and the organic molecules and extending continuously from the first electrode to the second electrode.

11. A capacitor, comprising:
a first metal-molecule capacitor plate, comprising;
a plurality of metal, semimetallic or semiconducting nanoparticles; and
a plurality of electrically conductive organic molecules interspersed among the nanoparticles.
a second capacitor plate;
an electrolyte material between the metal nanoparticles and the organic molecules in both the first plate and the second plate and continuously extending continuously from the first plate to the second plate; and
an electrical connection between the first plate and the second plate, the electrical connection capable of maintaining an applied potential difference between the first plate and the second plate.
